(19) United States
(12) Patent Application Publication
(10) Pub. No.: US 2024/0040837 A1
(43) Pub. Date: Feb. 1, 2024

(54) DISPLAY DEVICE

(71) Applicant: Samsung Display Co., Ltd., Yongin-si (KR)

(72) Inventor: DOOHYUN LEE, Yongin-si (KR)

(73) Assignee: Samsung Display Co., Ltd., Yongin-si (KR)

(21) Appl. No.: 18/336,192

(22) Filed: Jun. 16, 2023

(30) Foreign Application Priority Data
Jul. 26, 2022 (KR) 10-2022-0092715

(51) Int. Cl. H10K 59/121; H10K 59/123; H10K 59/122; H10K 59/65; H10K 59/35

(52) U.S. Cl. CPC H10K 59/1213; H10K 59/123; H10K 59/122; H10K 59/65; H10K 59/353

(57) ABSTRACT

A display device includes a display panel, wherein a first unit pixel is repeatedly disposed in a first display area, the first unit pixel and a second unit pixel are repeatedly disposed in a second display area, the first unit pixel comprises a red pixel, a green pixel, and a blue pixel, and the second unit pixel comprises a red pixel, a green pixel, a blue pixel, and an optical sensing pixel, the optical sensing pixel includes a transistor disposed on a substrate, a first electrode electrically connected to the transistor, a first common layer disposed on the first electrode, an optical sensing layer and a first emission layer disposed on the first common layer, and a second electrode disposed on the first emission layer and the optical sensing layer, and a planar area of the optical sensing layer is larger than a planar area of the first emission layer.

### CROSS-REFERENCE TO RELATED APPLICATION

This application claims priority under 35 U.S.C. § 119 from Korean Patent Application No. 10-2022-0092715 filed in the Korean Intellectual Property Office on Jul. 26, 2022, the entire contents of which are incorporated herein by reference.

### BACKGROUND

### 1. Technical Field

The disclosure relates to a display device.

### 2. Description of the Related Art

As an image display device, an organic electroluminescent display is being actively developed. The organic electroluminescent display may be different from a liquid crystal display (LCD), and may be a so-called self-emissive display device where a display may be realized by emitting a light emitting material, which may be an organic combination, included in an emission layer by recombining holes and electrons injected from a first electrode and a second electrode into the emission layer.

As an organic electroluminescent display is often referred to as an organic light emitting diode (OLED) display, and may include a first electrode, a hole transfer layer disposed on the first electrode, an emission layer disposed on the hole transport layer, an electron transfer layer disposed on the emission layer, and a second electrode disposed on the electron transport layer.

Holes may be injected from the first electrode, and the injected hole moves through the hole transport layer and may be injected into the emission layer. Electrons may be injected from the second electrode, and the injected electrons move through the electron transfer layer and may be injected into the emission layer. As holes and electrons injected into the emission layer recombine, excitons may be generated in the emission layer. The organic electroluminescent display emits light using the light produced upon the exciton falling back to the ground state. In addition, the organic electroluminescent display may not be limited to the configuration described above, and various modifications may be possible.

The above information disclosed in this Background section is only for enhancement of understanding of the background of the invention, and therefore it may contain information that does not form prior art under 35 U.S.C. § 102 that may be already known in this country to a person of ordinary skill in the art.

### SUMMARY

Embodiments are to provide a display device that can provide improved display quality while realizing high-resolution while including a photo-sensing pixel in a display area.

A display device according to an embodiment includes: a display panel that includes a first display area and a second display area, wherein a first unit pixel is repeatedly disposed in the first display area, the first unit pixel and a second unit pixel are repeatedly disposed in the second display area, the first unit pixel comprises a first red pixel, a first green pixel, and a first blue pixel, and the second unit pixel comprises a second red pixel, a second green pixel, a second blue pixel, and an optical sensing pixel, the optical sensing pixel includes a transistor disposed on a substrate; a first electrode electrically connected to the transistor; a first common layer disposed on the first electrode, an optical sensing layer and a first emission layer disposed on the first common layer; and a second electrode disposed on the first emission layer and on the optical sensing layer; and a planar area of the optical sensing layer is larger than a planar area of the first emission layer.

The first emission layer may emit green light.

The display device may further include a bank disposed on the first electrode, wherein an end of the optical sensing layer may be disposed on a top surface of the bank.

The optical sensing layer may be disposed on a side surface of the bank.

The bank may comprise an opening, and the first emission layer may be disposed within the opening.

A planar area of the optical sensing layer may be larger than a planar area of the opening.

The first emission layer may be disposed on the optical sensing layer.

The display device may further include a second common layer disposed between the optical sensing layer and the first emission layer, and a third common layer disposed on the first emission layer.

The optical sensing layer may be disposed on the first emission layer.

The display device may further include a second common layer disposed between the first emission layer and the optical sensing layer, and a third common layer disposed between the optical sensing layer and the second electrode.

The first red pixel may include a first red emission layer and a second red emission layer may be disposed on the first electrode, and the first common layer may be disposed between the first electrode and the first red emission layer, the second common layer may be disposed between the first red emission layer and the second red emission layer, and the third common layer may be disposed between the second red emission layer and the second electrode.

The display device may further include a bank arranged on the first electrode and including an opening, and the first red emission layer and the second red emission layer may be disposed within the opening.

In the second display area, the first unit pixel and the second unit pixel may be alternately disposed in the second display area.

The first display area may be larger than the second display area.

A display device according to an embodiment include includes a display panel that includes a first display area and a second display area, wherein the first display area may include a first unit pixel, the second display area may include the first unit pixel and a second unit pixel, the first unit pixel may include a first red pixel, a first green pixel, and a first blue pixel, the second unit pixel may include a second red pixel, a second green pixel, a second blue pixel, and an optical sensing pixel, the optical sensing pixel may include an optical sensing layer and a green emission layer arranged in an opening in a bank layer, the second red pixel, the second green pixel, the second blue pixel, and the optical sensing pixel may be defined by the opening of the bank layer, and the optical sensing layer may extend external to the opening.

An end of the optical sensing layer may be disposed on a top surface of the bank layer.

The green emission layer may be disposed within the opening.

The green emission layer may be disposed on the optical sensing layer.

The optical sensing layer may be disposed on the green emission layer.

The first unit pixel and the second unit pixel may be alternately disposed in the second display area.
disposed

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic perspective view that shows a use state of a display device according to an embodiment;

FIG. 2 is an exploded perspective view of the display device according to the embodiment;

FIG. 3 is a top plan view of a pixel disposed in the first display area according to the embodiment;

FIG. 4 is a top plan view of a pixel disposed in the second display area according to an embodiment;

FIG. 5 is a schematic cross-sectional view of the pixel disposed in the first display area according to the embodiment;

FIG. 6 is a schematic cross-sectional view of the pixel disposed in the second display area according to the embodiment; and

FIG. 7 is a schematic cross-sectional view of a pixel disposed in the second display area according to an embodiment.

### DETAILED DESCRIPTION OF THE EMBODIMENTS

With reference to the accompanying drawings, the disclosure will be described in detail and therefore a person of an ordinary skill in the art can easily implement it in the technical field to which the disclosure may be included. The disclosure may be implemented in several different forms and may not be limited to the embodiments described herein.

In order to clearly explain the disclosure, parts irrelevant to the description may be omitted, and a same reference sign may be designated to a same or similar constituent elements throughout the specification.

Since the size and thickness of each component shown in the drawings are arbitrary for better understanding and ease of description, the disclosure may not be necessarily limited to the drawings. In the drawings, the thickness of layers, films, panels, regions, etc., may be exaggerated for clarity. In the drawings, the thicknesses of some layers and regions may be exaggerated for better understanding and ease of description.

Unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

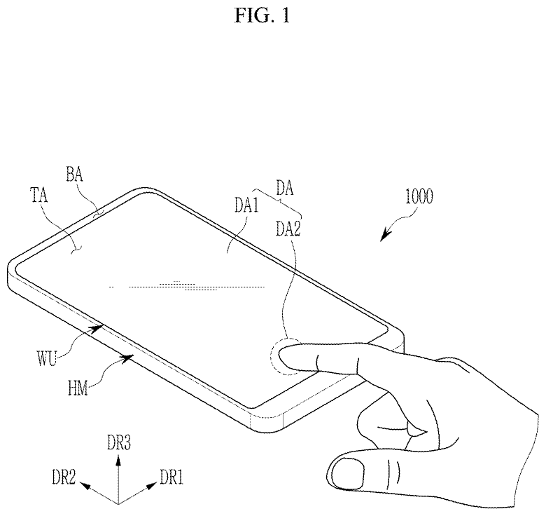

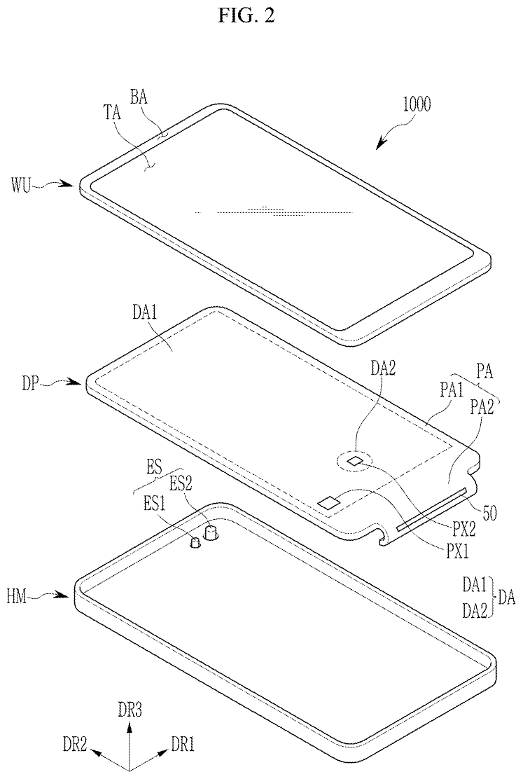

Hereinafter, a structure of a display device will be schematically described with reference to FIG. 1 to FIG. 2. FIG. 1 is a schematic perspective view that shows a use state of a display device according to an embodiment, and FIG. 2 is an exploded perspective view of the display device according to the embodiment.

Referring to FIG. 1, a display device 1000 according to an embodiment may be a device for displaying a motion picture or a still image, and may be used as a display screen of various products such not only portable electronic devices such as a mobile phone, a smart phone, a tablet personal computer (tablet PC), a mobile communication terminal, an electron notebook, electron book, a portable multimedia player (PMP), navigation, an ultra mobile PC (UMPC), the like, or a combination thereof, but also televisions, laptops, monitors, billboards, the Internet of Things (TOT), or a combination thereof. In addition, the display device 1000 according to the embodiment may be used in a wearable display such as a smart watch, a watch phone, a spectacles display, and a head mounted display (HMD). In addition, the display device 1000 according to the embodiment may be used as a dashboard of a vehicle, a center information display (CID) disposed on the center fascia or dashboard of the vehicle, a room mirror display that replaces the side mirror of the vehicle, and a display disposed on the back of the front seat for entertainment for the back seat of the vehicle. FIG. 1 illustrates that the display device 1000 may be used as a smart phone for better comprehension and ease of description.

The display device 1000 may display an image toward a third direction DR3 on a display surface that may be parallel to a first direction DR1 and a second direction DR2. The display surface on which the image may be displayed may correspond to a front surface of the display device 1000 and may correspond to a front surface of a cover window WU. Images may include still images as well as motion images.

In the embodiment, the front (or top) and rear (or bottom) of each member may be defined with reference to the direction in which the image may be displayed. The front and rear surfaces may be opposite to each other in the third direction DR3, and the normal directions of the front and rear surfaces may be parallel to the third direction DR3. A separation distance in the third direction DR3 between the front and rear surfaces may correspond to the thickness in the third direction DR3 of the display panel.

The display device 1000 according to the embodiment may detect a user's input (refer to the hand in FIG. 1) applied from the outside. The user's input may include various types of external inputs such as a part of the user's body, light, heat, or pressure. In the embodiment, the user's input may be shown with the user's hand applied to the front. However, the disclosure may not be limited thereto. The user's input may be provided in various forms, and the display device 1000 may also sense the user's input applied to the side or rear surface of the display device 1000 according to the structure of the display device 1000.

Referring to FIGS. 1 and 2, the display device 1000 may include a cover window WU, a housing HM, a display panel DP, and an optical element ES. In the embodiment, the cover window WU and the housing HM may be combined to form the appearance of the display device 1000.

A housing HM may be combined with the cover window WU. The cover window WU may be disposed in front of the housing HM. The housing HM may be combined with the cover window WU to provide a predetermined receiving space. The display panel DP and the optical element ES may be accommodated within a predetermined receiving space provided between the housing HM and the cover window WU.

The housing HM may contain a material with relatively high stiffness. For example, the housing HM may include multiple frames and/or plates made of glass, plastic, or metal, or a combination thereof. The housing HM may reliably protect the components of the display device 1000 received within the receiving space from external impact.

The cover window WU may include an insulating panel. For example, the cover window WU may be formed of glass, plastic, or a combination thereof.

The front of the cover window WU may define the front of the display device 1000. The cover window WU may include a blocking area BA surrounding a periphery of a transmissive area TA. The transmissive area TA may be an optically transparent area. For example, the transmissive area TA may be a region having a visible ray transmittance of about 90% or more.

The blocking area BA may define a shape of the transmissive area TA. The blocking area BA may be adjacent to the transmissive area TA and may surround a periphery of the transmissive area TA. The blocking area BA may be a region having relatively low light transmittance compared to the transmissive area TA, may include an opaque material that blocks light, may have a predetermined color, may be defined by a bezel layer provided separately from the transparent substrate defining the transmissive area TA, or may be defined by an ink layer formed by inserting or coloring the transparent substrate.

The display panel DP may include a display area DA and a driver 50 for displaying an image. The display panel DP may include a front surface including the display area DA and a non-display area PA. The display area DA may be a region in which a pixel operates and emits light according to an electrical signal.

In the embodiment, the display area DA may be a region including a pixel and in which an image may be displayed, and simultaneously a region in which an external input may be sensed by a touch sensor disposed on an upper side of the display panel DA in the third direction DR3 of the pixel.

The display area DA may include a first display area DA1 and a second display area DA2. The first display area DA1 and the second display area DA2 both can display images by including pixels. The second display area DA2 may also include a light sensing circuit (e.g., a fingerprint sensing pixel) for sensing a fingerprint from a user's input. The area of the second display area DA2 may be smaller than the area of the first display area DA1, but may not be limited thereto.

Multiple first pixels PX1 may be disposed in the first display area DA1, and multiple second pixels PX2 may be disposed in the second display area DA2. Specific details will be described later. The display area DA includes multiple light emitting diodes, and multiple pixels that generate and transmit a light emitting current to each of the light emitting diodes.

The transmissive area TA of the cover window WU may at least partially overlap (or is arranged over) the display area DA of the display panel DP. For example, the transmissive area TA may overlap the entire surface of the display area DA or may overlap at least a portion of the display area DA. Accordingly, the user may recognize an image through the transmissive area TA or provide an external input based on the image. However, the disclosure may not be limited thereto. For example, in the display area DA, a region where an image may be displayed and a region where an external input may be sensed may be separated from each other.

The non-display area PA of the display panel DP may at least partially overlap with the blocking area BA of the cover window WU. The non-display area PA may be a region covered by the blocking area BA. The non-display area PA may be adjacent to the display area DA and may surround the display area DA. An image may not be displayed in the non-display area PA, and a driving circuit or a driving wire for driving the display area DA may be disposed in the non-display area PA. The non-display area PA may include a first peripheral area PA1 disposed outside the display area DA, and a second peripheral area PA2 including a connection wire and a bending area. In an embodiment of FIG. 2, the first peripheral area PA1 may be disposed at three sides of the display area DA, and the second peripheral area PA2 may be disposed at the remaining side of the display area DA.

In an embodiment, the display panel DP may be assembled in a flat state with the display area DA and non-display area PA facing the cover window WU. However, the disclosure may not be limited thereto. For example, a part of the non-display area PA of the display panel DP may be bent. A portion of the non-display area PA faces a rear surface of the display device 1000 and thus the blocking area BA shown on the front surface of the display device 1000 may be reduced, and as shown in FIG. 2, the second peripheral area PA2 may be bent and disposed on the rear side of the display area DA and assembled.

The second peripheral area PA2 may include a bend portion. The display area DA and the first peripheral area PA1 may be flat and be disposed substantially parallel to a plane defined by the first direction DR1 and the second direction DR2, and a side of the second peripheral area PA2 may extend from the flat portion of the display panel and pass through the bend portion to the flat portion. Accordingly, a part of the second peripheral area PA2 may be bent and assembled to be disposed on the rear surface of the display area DA. Upon assembly, at least a part of the second peripheral area PA is arranged underneath the display area DA on a plane, and thus the blocking area BA of the display device 1000 may be reduced. However, the disclosure may not be limited thereto. For example, the second peripheral area PA2 may not be bent.

The driver 50 may be mounted on the second peripheral area PA2, and may be mounted on the bend portion or be disposed on either side of the bend portion. The driver 50 may be provided in the form of a chip.

The driver 50 may be electrically connected to the display area DA to transmit an electrical signal to the display area DA. For example, the driver 50 may provide data signals to the pixels PX1 and PX2 disposed in the display area DA. As another example, the driver 50 may include a touch driving circuit and may be electrically connected to a touch sensor disposed in the display area DA. The driver 50 may include various circuits in addition to the above-described circuits or may be designed to provide various electrical signals to the display area DA.

In the display device 1000, a pad portion may be disposed at an end of the second peripheral area PA2, and thus the second peripheral area PA2 may be electrically connected to a flexible printed circuit board (FPCB) including a driving chip by the pad portion. Here, the driving chip disposed in the flexible printed circuit board may include various driving circuits for driving the display device 1000 or a connector for power supply. Depending on embodiments, a rigid printed circuit board (PCB) may be used instead of the flexible printed circuit board.

The optical element ES may be disposed under the display panel DP. The optical element ES may include a first optical element ES1 and a second optical element ES2.

The first optical element ES1 may be an electronic element using light or sound. For example, the first optical element ES1 may be a sensor that receives and uses light like an infrared sensor, a sensor that outputs and senses light or sound to measure distance or recognize a fingerprint, and the like, a small lamp that outputs light, a speaker that outputs sound, and the like. In the case the optical element ES is an electronic element using light, light of various wavelength bands such as visible light, infrared light, ultraviolet (UV) light, or a combination thereof can be used.

The second optical element ES2 may be at least one of a camera, an infrared (IR) camera, a dot projector, an infrared illuminator, a time-of-flight (ToF) sensor, or a combination thereof.

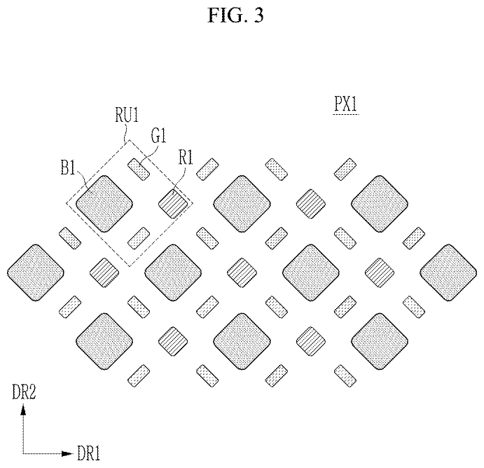

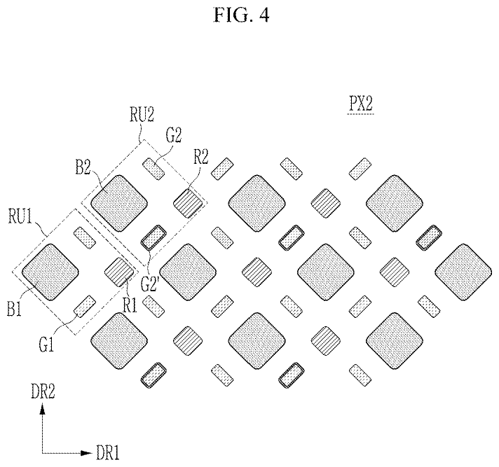

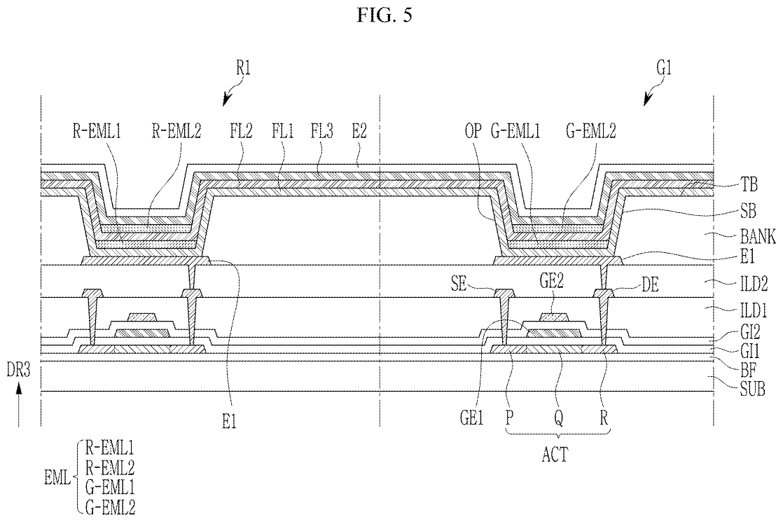

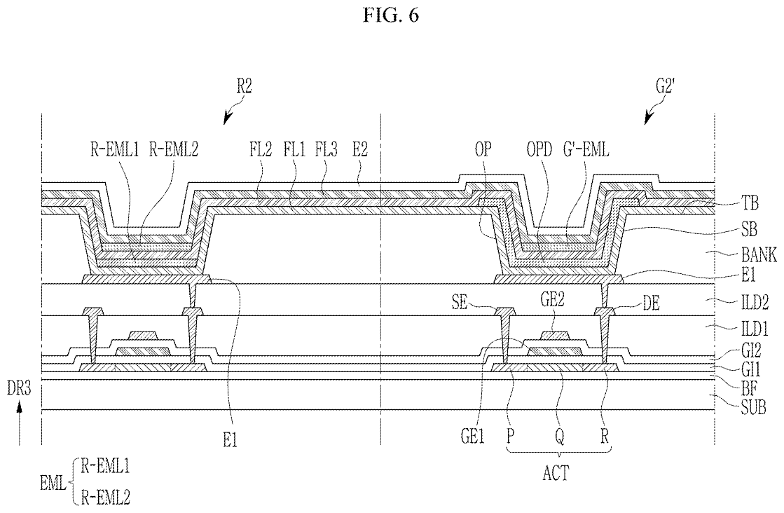

Hereinafter, referring to FIG. 3 to FIG. 6, the display area according to an embodiment will be described. FIG. 3 is a top plan view of a pixel PX1 disposed in the first display area DA1 according to an embodiment, FIG. 4 is a top plan view of a pixel PX2 disposed in the second display area DA2 according to an embodiment, FIG. 5 is a schematic cross-sectional view of the pixel PX1 disposed in the first display area DA1 according to the embodiment, and FIG. 6 is a schematic cross-sectional view of the pixel PX2 disposed in the second display area DA2 according to the embodiment.

Referring to FIG. 3, a first pixel PX1 may be disposed in the first display area DA1. In the first pixel PX1, a first unit pixel RU1 including four pixels selected from R1, G1, and B1 may be iteratively arranged. The four pixels constituting one first unit pixel RU1 may include one red pixel R1, one blue pixel B1, and two green pixels G1. However, depending on embodiments, at least one red pixel R1, at least one green pixel G1, and at least one blue pixel B1 may be included.

Referring to FIG. 4, a second pixel PX2 may be disposed in the second display area DA2. The second pixel PX2 includes a first unit pixel RU1 including four pixels selected from R1, G1, and B1, and a second unit pixel RU2 including four pixels that include R2, G2, B2, and G2′.

The four pixels constituting one first unit pixel RU1 may include one red pixel R1, one blue pixel B1, and two green pixels G1. However, depending on embodiments, at least one red pixel R1, at least one green pixel G1, and at least one blue pixel B1 may be included. In addition, the four pixels forming one second unit pixel RU2 may include one red pixel R2, one blue pixel B2, and two green pixels G2 and G2′. Any one of the two green pixels G2 and G2′ may be a photo-sensing pixel including a photo-sensing layer, but the scenario of G2′ being the photo-sensing pixel will now be discussed. The photo-sensing pixel G2′ may sense a user's input, and may be, for example, a fingerprint sensing pixel for detecting a fingerprint by the user's input. One green pixel G2 and one photo-sensing pixel G2′ may both emit green light, but the luminance of the emitted green light may be different.

In the second display area DA2 according to the embodiment, the first unit pixel RU1 and the second unit pixel RU2 may be alternately disposed. For example, the first unit pixel RU1 and the second unit pixel RU2 may be disposed to alternate along a diagonal direction with respect to the first direction DR1 and the second direction DR2. However, the disclosure may not be limited thereto, and the repetition form and arrangement of the first unit pixel RU1 and the second unit pixel RU2 may be variously changed.

Hereinafter, referring to FIG. 5, a schematic cross-section structure of the first unit pixels RU1 disposed in the first display area DA1 will be described. In the specification, the cross-section of the first red pixel R1 and the first green pixel Glare described, but this may be equally applied to the first blue pixel B1.

Referring to FIG. 5, the first pixels PX1 may be disposed on a substrate SUB. The substrate SUB may include an inorganic insulating material such as glass or an organic insulating material such as plastic such as polyimide (PI). The substrate SUB may be single-layered or multi-layered. The substrate SUB may have a structure in which at least one base layer containing a sequentially stacked polymer resin and at least one inorganic layer may be alternately stacked.

The substrate SUB may have various degrees of flexibility. The substrate SUB may be a rigid substrate or a flexible substrate that can be bent, folded, rolled, the like, or a combination thereof.

A buffer layer BF may be disposed on the substrate SUB. The buffer layer BF may block the transfer of impurities from the substrate SUB to layers disposed above the buffer layer BF, for example a semiconductor layer ACT, thereby preventing the characteristic degradation of the semiconductor layer ACT and reducing the stress. The buffer layer BF may include an inorganic insulating material or an organic insulating material such as a silicon nitride or a silicon oxide. A part or all of the buffer layer BF may be omitted.

The semiconductor layer ACT may be disposed on the buffer layer BF. The semiconductor layer ACT may include at least one of polysilicon and an oxide semiconductor. The semiconductor layer ACT includes a channel region Q, a first region P, and a second region R. The first region P and the second region R may be respectively disposed on opposing sides of the channel region Q. The channel region Q may include a semiconductor doped with a small amount of impurity or may be intrinsic, and the first region P and the second region R may include a semiconductor doped with a large amount of an impurity compared to the channel region Q. The semiconductor layer ACT may be formed of an oxide semiconductor. A separate protective layer (not shown) may be added to protect the oxide semiconductor material, which may be vulnerable to external conditions such as high temperature.

A first gate insulation layer GI1 may be disposed on the semiconductor layer ACT. A gate electrode GE1 may be disposed on the first gate insulation layer GI1 Depending on an embodiment, the gate electrode GE1 and a lower electrode of a storage capacitor may be integral with each other. The gate electrode GE1 may be a single layer or multilayer in which a metal film including any one of copper (Cu), a copper alloy, aluminum (Al), an aluminum alloy, molybdenum (Mo), a molybdenum alloy, titanium (Ti), a titanium alloy, or a combination thereof may be laminated. The gate electrode GE1 may overlap or be arranged on top of the channel region Q of the semiconductor layer ACT.

A second gate insulation layer GI2 may be disposed on the gate electrode GE1 and the first gate insulation layer GI1. The first gate insulation layer GI1 and the second gate insulation layer GI2 may be single-layered or multi-layered including at least one of a silicon oxide (SiOₓ), a silicon nitride (SiNₓ), a silicon oxynitride (SiOₓN_{y}), or a combination thereof.

An upper electrode GE2 may be disposed on the second gate insulation layer GI2. The upper electrode GE2 may overlap or be arranged on top of the lower electrode (or gate electrode) GE1 to form a storage capacitor.

A first interlayer insulation layer ILD1 may be disposed on the upper electrode GE2. The first interlayer insulation layer ILD1 may be single-layered or multi-layered including at least one of a silicon oxide (SiOₓ), a silicon nitride (SiNₓ), a silicon oxynitride (SiOₓN_{y}), or a combination thereof.

A source electrode SE and a drain electrode DE may be disposed on the first interlayer insulation layer ILD1. The source electrode SE and the drain electrode DE may be electrically connected to the first region P and the second region R respectively of the semiconductor layer ACT through contact holes formed in the insulation layers.

The source electrode SE and the drain electrode DE may include aluminum (Al), silver (Ag), magnesium (Mg), gold (Au), nickel (Ni), chromium (Cr), nickel (Ni), calcium (Ca), molybdenum (Mo), titanium (Ti), tungsten (W), copper (Cu), or a combination thereof and may be a single-layer or multi-layer structure including the same.

A second interlayer insulation layer ILD2 may be disposed on the first interlayer insulation layer ILD1, the source electrode SE, and the drain electrode DE. The second interlayer insulation layer ILD2 may include an organic insulating material such as a general-purpose polymer such as polymethylmethacrylate (PMMA) or polystyrene (PS), a polymer derivative with phenolic groups, an acryl-based polymer, an imide-based polymer, polyimide, an acryl-based polymer, a siloxane-based polymer, the like, or a combination thereof.

The first electrode E1 may be disposed on the second interlayer insulation layer ILD2. The first electrode E1 may be electrically connected to the drain electrode DE through a contact hole of the second interlayer insulation layer ILD2.

The first electrode E1 may include a metal such as silver (Ag), lithium (Li), calcium (Ca), aluminum (Al), magnesium (Mg), or gold (Au), or may include a transparent conductive oxide (TCO) such as an indium tin oxide (ITO) and an indium zinc oxide (IZO). The first electrode E1 may be formed of a single layer including a metallic material or a transparent conductive oxide, or a multi-layer including them. For example, the first electrode E1 may have a triple layer structure of indium tin oxide (ITO)/silver (Ag)/indium tin oxide (ITO).

A transistor formed of the gate electrode GE1, the semiconductor layer ACT, the source electrode SE, and the drain electrode DE may be electrically connected to the first electrode E1 to supply a current to a light emitting element.

Partitioning walls or bank layers or banks BANK may be disposed on the second interlayer insulation layer ILD2 and the first electrode E1. Although not shown, a spacer (not shown) may be disposed on the bank BANK. The bank BANK overlaps (or is arranged on top of) at least a portion of the first electrode E1. The bank BANK may include a top or upper surface TB perforated by an opening OP that defines a light emitting area, and may further include sidewalls SB disposed between the opening OP and adjoining portions of top surface TB.

The bank BANK may include an organic insulating material such as a general-purpose polymer such as polymethylmethacrylate (PMMA) or polystyrene (PS), a polymer derivative with phenolic groups, an acryl-based polymer, an imide-based polymer, polyimide, an acryl-based polymer, a siloxane-based polymer, the like, or a combination thereof.

A first common layer FL1, a second common layer FL2, a third common layer FL3, an emission layer EML, and a second electrode E2 may be disposed on the first electrode E1 and bank BANK.

The emission layer EML may include red emission layers R-EML1 and R-EML2, green emission layers G-EML1 and G-EML2, and blue emission layers. The first red pixel R1 according to the embodiment may include a first red emission layer R-EML1 and a second red emission layer R-EML2. The first green pixel G1 may include a first green emission layer G-EML1 and a second green emission layer G-EML2. Although not shown, the first blue pixel B1 may include a first blue emission layer and a second blue emission layer.

Each emission layer EML included in the pixels R1, G1, and B1 included in the first unit pixel PX1 may be confined to or arranged only within the opening OP in the bank BANK. For example, the first red emission layer R-EML1 and the second red emission layer R-EML2 may not be disposed on the top surface TB of the bank BANK. Likewise the first green emission layer G-EML1 and the second green emission layer G-EML2 may not be disposed on the top surface TB of the bank BANK. Similarly the first blue emission layer and the second blue emission layer may not be disposed on the top surface TB of the bank BANK.

The first common layer FL1 may be disposed between the first electrode E1 and the first red emission layer R-EML1. The second common layer FL2 may be disposed between the first red emission layer R-EML1 and the second red emission layer R-EML2. The third common layer FL3 may be disposed between the second red emission layer R-EML2 and the second electrode E2.

The first common layer FL1 may be disposed between the first electrode E1 and the first green emission layer G-EML1. The second common layer FL2 may be disposed between the first green emission layer G-EML1 and the second green emission layer G-EML2. The third common layer FL3 may be disposed between the second green emission layer G-EML2 and the second electrode E2.

The first common layer FL1, the second common layer FL2, the third common layer FL3, and the second electrode E2 according to the embodiment may be continuously formed over the first red pixel R1 and the first green pixel G1. In addition, the first common layer FL1, the second common layer FL2, the third common layer FL3, and the second electrode E2 may be continuously formed over the entire first display area DA1 and the second display area DA2.

The first common layer FL1 may include a hole transport region. The hole transport region may include a hole injection layer (HIL), a hole transport layer (HTL), an electron blocking layer, or any combination thereof.

The hole transport region may be formed using a general technique. For example, the hole transport region may be formed using various techniques such as vacuum deposition, spin coating, casting, Langmuir-Blodgett (LB), inkjet printing, laser printing, laser induced thermal imaging (LITI), or a combination thereof.

The hole injection layer (HIL) included in the hole transport region may contain a hole injection material. The hole injection material may include a phthalocyanine compound such as copper phthalocyanine; DNTPD(N,N′-diphenyl-N,N′-bis-[4-(phenyl-m-tolyl-amino)-phenyl]-biphenyl-4,4′-diamine), m-MTDATA (4,4′,4″-[tris (3-methylphenyl)phenylamino] triphenylamine), TDATA (4,4′4″-Tris(N,N-diphenylamino)triphenylamine), 2-TNATA (4,4′,4″-tris[N,-(2-naphthyl)-N-phenylamino]-triphenylamine), PEDOT/PSS (Poly (3,4-ethylenedioxythiophene)/Poly (4-styrenesulfonate)), polyaniline/dodecylbenzenesulfonic acid (PANI/DBSA), polyaniline/camphor sulfonicacid (PANI/CSA), PANI/PSS (Polyaniline/Poly (4-styrenesulfonate)), NPB(N,N′-di(naphthalene-1-yl)-N,N′-diphenyl-benzidine), NPD(N,N′-Di (1-naphthyl)-N,N′-diphenyl-(1,1′-biphenyl)-4,4′-diamine), polyetherkethone (TPAPEK) including triphenylamine, 4-Isopropyl-4′-methyldiphenyliodonium [Tetrakis(pentafluorophenyl)borate], HAT-CN(dipyrazino[2,3-f:2′,3′-h] quinoxaline-2,3,6,7,10,11-hexacarbonitrile), the like, or a combination thereof.

The hole transport layer (HTL) included in the hole transport region may include a hole transport material. The hole transport material may include at least one of a carbazole-based derivative such as N-phenylcarbazole, polyvinylcarbazole, and the like, a fluorene-based derivative, a triphenylamine-based derivative such as TPD(N,N′-bis (3-methylphenyl)-N,N′-diphenyl-[1,1-biphenyl]-4,4′-diamine), TCTA (4,4′,4″-tris(N-carbazolyl)triphenylamine), and the like, NPB(N,N′-di(naphthalene-1-yl)-N,N′-diphenyl-benzidine), TAPC (4,4′-Cyclohexylidene bis[N,N-bis (4-methylphenyl)benzenamine]), HMTPD (4,4′-Bis[N,N-(3-tolyl)amino]-3,3′-dimethylbiphenyl), mCP (1,3-Bis(N-carbazolyl)benzene), CzSi (9-(4-tert-Butylphenyl)-3,6-bis(triphenylsilyl)-9H-carbazole), m-MTDATA (4,4′,4″-[tris (3-methylphenyl)phenylamino] triphenylamine), and the like.

A thickness of the hole transport region may be from about 100 Å to about 10000 Å, for example, from about 100 Å to about 5000 Å. A thickness of the hole injection layer may be, for example, about 30 Å to about 1000 Å, and a thickness of the hole transport layer may be about 30 Å to about 1000 Å. In case that the thickness of the hole transport region, the thickness of the hole injection layer, and the thickness of the hole transport layer satisfy the above-mentioned ranges, a satisfactory level of hole transport characteristics can be obtained without a substantial increase in driving voltage.

The electron blocking layer may be a layer that prevents electrons from leaking from the electron transport region to the hole transport region. A thickness of the electron blocking layer may be about 10 Å to about 1000 Å. The electron blocking layer may include, for example, a carbazole-based derivative such as N-phenylcarbazole, polyvinylcarbazole, the like, or a combination thereof, a fluorene-based derivative, a triphenylamine-based derivative such as TPD(N,N′-bis (3-methylphenyl)-N,N′-diphenyl-[1,1-biphenyl]-4,4′-diamine), TCTA (4,4′,4″-tris(N-carbazolyl)triphenylamine), and the like, NPD(N,N′-di(naphthalene-1-yl)-N,N′-diplienyl-benzidine), TAPC (4,4′-Cyclohexylidene bis[N,N-bis (4-methylphenyl)benzenamine]), HMTPD (4,4′-Bis[N,N′-(3 -tolyl)amino]-3,3′-dimethylbiphenyl), mCP, the like, or a combination thereof.

The hole transport region may further include a charge generating material for conductive improvement in addition to the above-mentioned materials. The charge generating material may be uniformly or non-uniformly distributed within the hole transport region. The charge generating material may be, for example, a p-dopant. The p-dopant may be one of quinone derivatives, metal oxides, cyano group-containing compounds, or a combination thereof but may not be limited thereto. For example, as a non-limiting example of a p-dopant, a quinone derivative such as tetracyanoquinodimethane (TCNQ) and F4-TCNQ (2,3,5,6-tetrafluoro-7,7′,8,8′-tetracyanoquinodimethane), a metal oxide such as a tungsten oxide and a molybdenum oxide, the like, or a combination thereof may be included, this may not be restrictive.

The second common layer FL2 may contain an electron transport region. The electron transport region may include a hole blocking layer, an electron transport layer (ETL), an electron injection layer (EIL), or any combination thereof.

Each layer of the electron transport region can be formed using common techniques. For example, the hole transport region may be formed using various techniques such as vacuum deposition, spin coating, casting, Langmuir-Blodgett (LB), inkjet printing, laser printing, laser induced thermal imaging (LITI), or a combination thereof.

The electron injection layer included in the electron transport region may include an electron injection material. The electron injection material may be a halogenated metal such as LiF, NaCl, CsF, RbCl or RbI, a lanthanide metal such as Yb, a metal oxide such as Li₂O or BaO, lithium quinolate (LiQ), or a combination thereof but may not be limited thereto. The electron injection layer may also be formed of a mixture of an electron transport material and an insulating organic metal salt. The organic metal salt may be a material having an energy band gap of about 4 eV or more. Specifically, for example, the organic metal salt includes metal acetate, metal benzoate, metal acetoacetate, metal acetylacetonate, or metal stearate.

An electron transport layer included in the electron transport region may include an electron transport material. The electron transport material may include a triazine-based compound, an anthracene-based compound, or a combination thereof. However, this may not be restrictive, and the electron transport material may include, for example, Alq₃ (Tris (8-hydroxyquinolinato)aluminum), 1,3,5 -tri[(3 -pyridyl)-phen-3 -yl]benzene, 2,4,6-tris (3′-(pyridin-3 -yl)biphenyl-3 -yl)-1,3,5-triazine, 2-(4-(N-phenylbenzoimidazolyl-1-ylphenyl)-9,10-dinaphthylanthracene, TPBi (1,3,5-tris (1-phenyl-1H-benzo[d]imidazol-2-yl)benzene), BCP (2,9-Dimethyl-4,7-diphenyl-1,10-phenanthroline), Bphen (4,7-Diphenyl-1,10-phenanthroline), TAZ (3-(4-Biphenylyl)-4-phenyl-5-tert-butylphenyl-1,2,4-triazole), NTAZ (4-(Naphthalen-1-yl)-3,5-diphenyl-4H-1,2,4-triazole), tBu-PBD (2-(4-Biphenylyl)-5-(4-tert-butylphenyl)-1,3,4-oxadiazole), BAlq(Bis (2-methyl-8-quinolinolato-N1,O8)-(1,1′-Biphenyl-4-olato)aluminum), Bebq₂(berylliumbis(benzoquinolin-10-olate), ADN (9,10-di(naphthalene-2-yl)anthracene), TSP01(diphenyl (4-(triphenylsilyl)phenyl)phosphine oxide), TPM-TAZ (2,4,6-Tris (3-(pyrimidin-5-yl)phenyl)-1,3,5-triazine),or a mixture thereof.

Each electron injection layer may have a thickness of about 1 Å to about 500 Å, for example, about 3 Å to about 300 Å. In case that the thickness of the electron injection layer satisfies the above range, satisfactory electron injection characteristics can be obtained without a substantial increase in driving voltage.

The thickness of each electron transport layer may be about 100 Å to about 1000 Å, for example, about 150 Å to about 500 Å. In case that the thickness of the electron transport layer satisfies the range as described above, satisfactory electron transport characteristics can be obtained without a substantial increase in driving voltage.

The hole blocking layer may be a layer that prevents holes from leaking from the hole transport region into the electron transport region. A thickness of the hole blocking layer may be about 10 Å to about 1000 Å. The hole blocking layer may include at least one of BCP (2,9-dimethyl-4,7-diphenyl-1,10-phenanthroline), Bphen (4,7-diphenyl-1,10-phenanthroline), T2T (2,4,6-tri ([1,1′-biphenyl]-3-yl)-1,3,5-triazine), or a combination thereof, but this may not be restrictive.

The second common layer FL2 according to the embodiment may include an N-type charge generating layer providing electrons and/or a P-type charge generating layer providing holes. Depending on embodiments, a buffer layer may be further disposed between the N-type charge generating layer and the P-type charge generating layer.

The charge generating layer may generate charges (electrons and holes) by forming a complex through an oxidation-reduction reaction in case that a voltage may be applied. The charge generation layer may provide the generated charges to the adjacent emission layer EML.

The third common layer FL3 may include the aforementioned electron transport region and/or buffer layer.

The emission layer EML according to the embodiment may include at least one selected from an organic compound and a semiconductor compound, but may not be limited thereto. In case that the emission layer EML includes an organic compound, a light emitting element may be referred to as an organic light emitting element.

The organic compound may contain a host and a dopant. The semiconductor compound may be a quantum dot, For example, the light emitting element may be a quantum dot light emitting element. As another example, the semiconductor compound may be an organic and/or inorganic perovskite.

A thickness of the emission layer EML may be about 0.1 nm to about 100 nm. Specifically, the thickness of the emission layer EML may be about 15 nm to about 50 nm. More specifically, in case that the emission layer EML emits blue light, the thickness of the blue emission layer may be about 15 nm to about 20 nm, and in case that the emission layer emits green light, the thickness of the green emission layer may be about 20 nm to about 40 nm, and in case that the emission layer emits red light, the thickness of the red emission layer may be about 40 nm to about 50 nm. In case that the thickness of the emission layer EML satisfies the above-described range, the light emitting element may exhibit excellent light emitting characteristics without a substantial increase in driving voltage.

The emission layer EML may include a host material and a dopant material. The emission layer EML may be formed by using a phosphorescent or fluorescent light emitting material as a dopant in the host material. The emission layer EML may be formed by including a thermally activated delayed fluorescence (TADF) dopant in the host material. As another example, the emission layer EML may include a quantum dot material as a light emitting material. The core of the quantum dot may be selected from a group II-VI compound, a group III-V compound, a group IV-VI compound, a group IV element, and a group IV compound, and a combination thereof.

A color of the light emitted from the emission layer EML may be determined by the combination of the host material and the dopant material, or the type of quantum dot material and the size of the core.

The host material of the emission layer EML may be selected from fluoranthene derivative, pyrene derivative, arylacetylene derivative, anthracene derivative, fluorene derivatives, perylene derivatives, chrysene derivatives, the like, or a combination thereof. The host material for the emission layer EML may be selected from pyrene derivative, perylene derivative, anthracene derivative, or a combination thereof.

A dopant material of the emission layer EML may include a styryl derivative (e.g., 1,4-bis[2-(3-N-ethylcarbazoryl)vinyl]benzene(BCzVB), 4-(di-p-tolylamino)-4′-[(di-p-tolylamino)styryl]stilbene(DPAVB), N-(4-((E)-2-(6-((E)-4-(diphenylamino)styryl)naphthalen-2-yl)vinyl)phenyl)-N-phenylbenzenamine(N-BDAVBi), perylene and a perylene-based derivative (e.g., 2,5,8,11-Tetra-t-butylperylene(TBP)), pyrene and a pyrene-based derivative (e.g., 1,1-dipyrene, 1,4-dipyrenylbenzene, 1,4-Bis(N, N-Diphenylamino)pyrene), N1,N6-di(naphthalen-2-yl)-N1,N6-diphenylpyrene-1,6-diamine), the like, or a combination thereof.

The thickness of the second electrode E2 may be 5 nm to 20 nm. In case that the above-mentioned range may be satisfied, light absorption by the second electrode can be minimized, and satisfactory electron injection characteristics can be obtained without substantial increase in driving voltage.

Hereinafter, schematic cross-sectional views of the second red pixel R2 and the photo-sensing pixel G2′ included in the second display area DA2 will be described with reference to FIG. 6. Although FIG. 6 does not illustrate cross-sections of the second green pixel G2 and the second blue pixel B2 illustrated in FIG. 4, the cross-sections of the second green pixel G2 and the second blue pixel B2 may be the same as that of the second red pixel R2. In addition, the cross-section of the second red pixel R2 may be the same as that of the first red pixel R1 illustrated in FIG. 5, and therefore a description of the duplicated structure will be omitted.

Hereinafter, a photo-sensing pixel G2′ will be described. In the photo-sensing pixel G2′, an optical sensing layer OPD may be disposed on the first common layer FL1. The second common layer FL2 may be disposed on the optical sensing layer OPD. The optical sensing layer OPD may be a photoelectric conversion layer.

The optical sensing layer OPD may be disposed within an opening OP of the bank BANK. In addition, the optical sensing layer OPD may be formed wider than the opening OP. The planar area (i.e., an area occupied when viewed from a top or plan view) of the optical sensing layer OPD may be larger than the planar area of the opening OP.

The optical sensing layer OPD may be disposed on the sidewalls SB of the bank BANK and on an adjoining portion of upper surface TB of the bank BANK. An end of the optical sensing layer OPD may be disposed on the upper surface TB of the bank BANK. In case that the first common layer FL1 to the third common layer FL3 may be continuously formed on the entire surface of the substrate SUB, there may be a problem in that leakage current increases between adjacent pixels. Therefore, the red emission layers R-EML1 and R-EML2 may be confined to or disposed only within the opening OP. In contrast, the optical sensing layer OPD may extend beyond the opening OP so that the user's input can be more readily sensed.

A green emission layer G′-EML may be disposed on the second common layer FL2 and within the photo-sensing pixel G2′. Unlike the optical sensing layer OPD, the green emission layer G′-EML may be confined to or disposed only within the opening OP. The planar area (the area occupied when viewed from a top or plan view) of the green emission layer G′-EML included in the photo-sensing pixel G2′ may be smaller than the planar area of the optical sensing layer OPD.

The photo-sensing pixel G2′ according to the embodiment may emit green light due to the green emission layer G′-EML. As shown in FIG. 5, green light emitted from the photo-sensing pixel G2′ may have lower luminance compared to light emitted from the first green pixel G1 in which two green emission layers G-EML1 and G-EML2 may be stacked.

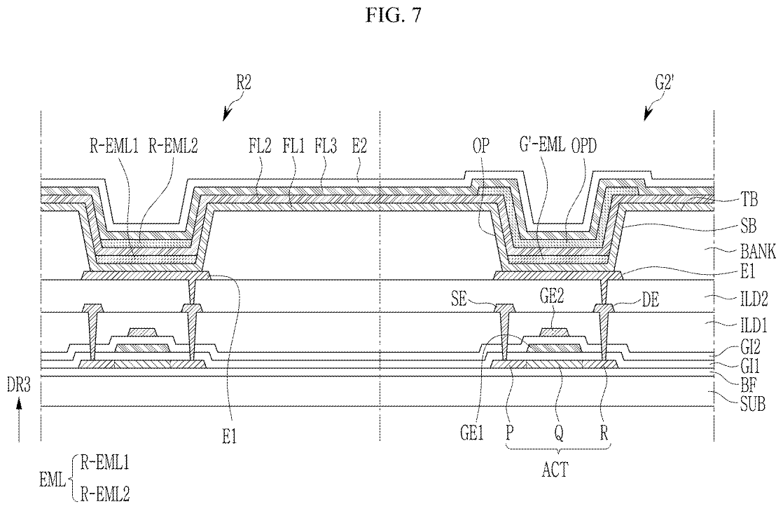

Hereinafter, referring to FIG. 7, a second display area DA2 according to an embodiment will be described. FIG. 7 is a schematic cross-sectional view of a pixel disposed in the second display area DA2 according to an embodiment. A description of the constituent elements described in the above drawing will be omitted.

In a photo-sensing pixel G2′ according to an embodiment, a first common layer FL1 may be disposed on a first electrode E1, and a green emission layer G′-EML may be disposed on the first common layer FL1. A second common layer FL2 may be disposed on the green emission layer G′-EML, and an optical sensing layer OPD may be disposed on the second common layer FL2. A third common layer FL3 and a second electrode E2 may be disposed on the optical sensing layer OPD.

Unlike the optical sensing layer OPD, the green emission layer G′-EML disposed on the first common layer FL1 may be confined to or disposed only within an opening OP. The planar area of the green emission layer G′-EML included in the photo-sensing pixel G2′ may be smaller than that of the optical sensing layer OPD.

The optical sensing layer OPD may be disposed to cover a part of side SB and top surfaces TB of a bank BANK that surround opening OP. The end of the optical sensing layer OPD may be disposed on the top surface TB of the bank BANK. In case that the first common layer FL1 to the third common layer FL3 may be continuously formed on the entire surface of the substrate SUB, there may be a problem in that leakage current increases between adjacent pixels. Therefore, the red emission layers R-EML1 and R-EML2 may be formed to be disposed only within the opening OP. Unlike the emission layers EML, the optical sensing layer OPD may extend beyond the opening OP so that an input from a user may be readily sensed.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A display device comprising:
a display panel that includes a first display area and a second display area, wherein
a first unit pixel is repeatedly disposed in the first display area,
the first unit pixel and a second unit pixel are repeatedly disposed in the second display area,
the first unit pixel comprises a first red pixel, a first green pixel, and a first blue pixel, and the second unit pixel comprises a second red pixel, a second green pixel, a second blue pixel, and an optical sensing pixel,
the optical sensing pixel comprises:
a transistor disposed on a substrate;
a first electrode electrically connected to the transistor;
a first common layer disposed on the first electrode,;
an optical sensing layer and a first emission layer disposed on the first common layer; and
a second electrode disposed on the first emission layer and the optical sensing layer, and
a planar area of the optical sensing layer is larger than a planar area of the first emission layer.

2. The display device of claim 1, wherein the first emission layer emits green light.

3. The display device of claim 1, further comprising:
a bank disposed on the first electrode,
wherein an end of the optical sensing layer is disposed on a top surface of the bank.

4. The display device of claim 3, wherein the optical sensing layer is disposed on a side surface of the bank.

5. The display device of claim 3, wherein:
the bank comprises an opening, and
the first emission layer is disposed within the opening.

6. The display device of claim 5, wherein a planar area of the optical sensing layer is larger than a planar area of the opening.

7. The display device of claim 1, wherein the first emission layer is disposed on the optical sensing layer.

8. The display device of claim 7, further comprising:
a second common layer disposed between the optical sensing layer and the first emission layer; and
a third common layer disposed on the first emission layer.

9. The display device of claim 1, wherein the optical sensing layer is disposed on the first emission layer.

10. The display device of claim 9, further comprising:
a second common layer disposed between the first emission layer and the optical sensing layer; and
a third common layer disposed between the optical sensing layer and the second electrode.

11. The display device of claim 8, wherein:
the first red pixel comprises a first red emission layer and a second red emission layer disposed on the first electrode, and
the first common layer being disposed between the first electrode and the first red emission layer, the second common layer being disposed between the first red emission layer and the second red emission layer, and the third common layer being disposed between the second red emission layer and the second electrode.

12. The display device of claim 11, further comprising:
a bank disposed on the first electrode and including an opening, the first red emission layer and the second red emission layer being disposed within the opening.

13. The display device of claim 1, wherein the first unit pixel and the second unit pixel are alternately disposed in the second display area.

14. The display device of claim 1, wherein the first display area is larger than the second display area.

15. A display device comprising:
a display panel that includes a first display area and a second display area, wherein
the first display area comprises a first unit pixel,
the second display area comprises the first unit pixel and a second unit pixel,
the first unit pixel comprises a first red pixel, a first green pixel, and a first blue pixel,
the second unit pixel comprises a second red pixel, a second green pixel, a second blue pixel, and an optical sensing pixel,
the optical sensing pixel comprises an optical sensing layer and a green emission layer arranged in an opening in a bank layer,
the second red pixel, the second green pixel, the second blue pixel, and the optical sensing pixel are defined by the opening of the bank layer, and
the optical sensing layer extends external to the opening.

16. The display device of claim 15, wherein an end of the optical sensing layer is disposed on a top surface of the bank layer.

17. The display device of claim 16, wherein the green emission layer is disposed within the opening.

18. The display device of claim 15, wherein the green emission layer is disposed on the optical sensing layer.

19. The display device of claim 15, wherein the optical sensing layer is disposed on the green emission layer.

20. The display device of claim 15, wherein the first unit pixel and the second unit pixel are alternately disposed in the second display area.
